(19) United States
(12) Patent Application Publication
(10) Pub. No.: US 2025/0266341 A1
(43) Pub. Date: Aug. 21, 2025

(54) SEMICONDUCTOR SUBSTRATE STRUCTURE WITH MICROCHANNEL PLATE-BASED VIAS AND METHOD FOR MANUFACTURING THE SAME

(71) Applicant: Woonkyung LEE, Seongnam-si (KR)

(72) Inventors: Woonkyung LEE, Seongnam-si (KR); Byung Hun LEE, Seongnam-si (KR)

(73) Assignee: Woonkyung LEE, Seongnam-si (KR)

(21) Appl. No.: 19/046,328

(22) Filed: Feb. 5, 2025

(30) Foreign Application Priority Data
Feb. 20, 2024 (KR) 10-2024-0024284
Jan. 20, 2025 (KR) 10-2025-0008145

(51) Int. Cl. H01L 23/498; H01L 21/48

(52) U.S. Cl. CPC H01L 23/49827; H01L 21/486

(57) ABSTRACT

A semiconductor substrate structure with through vias for electrical connection, includes: a microchannel plate substrate wherein multiple microchannels are arranged parallel and adjacent to each other at a predetermined angle to the surface; vias formed by utilizing one or more of microchannels in the substrate as via holes; and insulating layers covering the top and bottom of the substrate in regions excluding the vias.

### CROSS-REFERENCE TO PRIOR APPLICATIONS

This application claims priority to Korean Patent Application Nos. 10-2024-0024284 (filed on Feb. 20, 2024) and 10-2025-0008145 (filed on Jan. 20, 2025), which are all hereby incorporated by reference in their entirety.

### BACKGROUND

The present invention relates to a semiconductor substrate structure having high-quality vias and a cost-effective method for manufacturing the semiconductor substrate structure.

As semiconductor technology advances, chip performance has steadily improved. In particular, the rise and development of AI have driven increasing demand for high-speed processing, functional integration, device miniaturization, and low-power integrated circuits. This has led to a need for improving connection methods between chips and systems. To address the physical limitations and performance constraints of traditional wire bonding methods, innovative connection methods utilizing interposers or silicon bridges have been proposed. Interposers are primarily utilized in 2.5D and 3D packaging, serving as intermediaries to facilitate electrical connections between different semiconductor chips. They offer shorter electrical paths, enhanced signal transmission characteristics, and optimized thermal management solutions. This facilitates 3D connections between chips or between chips and systems, enhancing integration density and performance while supporting miniaturization.

An interposer comprises a substrate with vias that enable vertical electrical connections between chips and other electronic components, along with a redistribution layer (RDL) stacked on the substrate. The RDL redistributes the chip's I/O pads and signals to optimize connections with the package substrate or other chips. Vias are fine holes, known as via holes, penetrating the substrate and filled with conductive materials, serving as structural elements that enable vertical electrical connections between semiconductor chips across multiple layers. Vias allow chips or layers in a multilayer structure to be closely integrated, maximizing space utilization and shortening electrical paths. The RDL is used to resolve misalignment between original I/O pad positions and package substrate connection pad positions, enabling efficient communication between the chip and external components.

Interposers are categorized as silicon, organic, or glass interposers depending on the substrate material, each offering distinct advantages and disadvantages that can be appropriately chosen based on application requirements, cost considerations, and performance objectives. The formation of via holes is a critical process in interposer manufacturing, primarily employing etching (dry or wet), drilling, or laser ablation. The via hole diameter, aspect ratio, and wall flatness are critical factors influencing the reliability and performance of semiconductors using interposers. Appropriate fabrication methods can be selected based on the substrate material and the intended application of the interposer.

Silicon interposers can achieve vias with high aspect ratios exceeding 10 and highly flat, uniform walls, due to silicon's exceptional mechanical strength and precise manufacturing processes. This allows for high-density electrical connections, and their superior thermal conductivity effectively dissipates heat generated by chips. Therefore, they are particularly useful in high-performance computing applications. However, their relatively high rigidity and limited flexibility make them less suitable for flexible packaging solutions. The via manufacturing process is also complex and costly. Consequently, they are mainly used in high-speed networking and server chip applications where cost is not a primary concern. To improve the performance of silicon interposers, there has been a need to lower the dielectric constant of the substrate portions excluding vias. To achieve this, additional processes for creating air gaps within the substrate have been proposed. This results in increased process costs, necessitating more efficient alternatives.

Organic materials have a coefficient of thermal expansion similar to that of PCBs (printed circuit boards), resulting in low thermal stress and high reliability. They are also relatively easy to process, leading to lower manufacturing costs. However, the physical properties of organic materials and the limitations of manufacturing processes make it challenging to form high aspect ratio vias, which leads to greater electrical losses in high-frequency applications compared to silicon interposers. Additionally, their low thermal conductivity and thermal stability make them unsuitable for applications where thermal management is critical.

Glass interposers provide vias with characteristics intermediate between those of silicon and organic interposers with respect to aspect ratio and wall flatness. Particularly when using laser drilling and precision etching processes, they can provide high-quality vias. Their low dielectric constant and low electrical losses enable excellent electrical connections. Furthermore, their high thermal stability provides stable performance across a wide temperature range. The transparency of glass enhances its utility in certain types of applications. Glass is less expensive than silicon in terms of material costs and offers excellent cost efficiency when provided in panel form. However, the via formation process is technically complex and requires precise control, making manufacturing difficult and time-consuming, which may reduce competitiveness compared to silicon interposers.

As observed in the interposers of each material, the process of forming high-quality vias with high aspect ratios is a key factor in determining both performance and price competitiveness in interposer manufacturing. Therefore, a breakthrough method capable of forming high-quality vias through simpler processes is required. Additionally, as the number of stacked chips in packaging increases and becomes more multilayered, the number of vias and nodes is increasing exponentially. Consequently, it becomes increasingly important to provide excellent electrical connections through smaller-diameter vias.

Meanwhile, as illustrated in FIG. 1, a microchannel plate (also known as a capillary plate) is a substrate with multiple holes (i.e., microchannels) of uniform micro-diameter extending through the substrate from one surface to the other, aligned at a predetermined angle to the surface. Typically, microchannels are aligned perpendicular to the surface; however, depending on the application, they may be aligned at angles other than 90 degrees. Microchannel plates are extensively utilized in filtration devices, window materials for UV light sources or X-ray sources, collimators, electron multipliers, photomultipliers, time-of-flight (TOF) devices such as mass spectrometers, scanning electron microscopes, and residual gas analyzers. Recently, their applications have expanded to encompass analysis in biomedical fields. To address this trend, the present inventors have secured Korean Registered Patent No. 10-2563382 for an economical mass-production method for manufacturing microchannel plates and Korean Registered Patent No. 10-2546090 for electronic device based on multilayer thin film and using manufacturing microchannel plates.

### SUMMARY

The present invention aims to provide a semiconductor substrate structure capable of achieving high-density electrical connections through smaller via areas by utilizing high-quality vias with excellent signal transmission performance, while also exhibiting superior thermal stability due to increased contact area with surrounding insulators.

Another objective of the present invention is to provide a method for the economical mass production of the aforementioned semiconductor substrate structure through simplified processes.

The present invention further aims to provide a precursor that can be used in manufacturing the semiconductor substrate structure, as well as the applications of that precursor.

The technical problems to be solved by the present invention will be readily understood by those skilled in the art, even if not explicitly mentioned above.

To achieve the aforementioned objectives, the present invention pertains to a semiconductor substrate structure featuring through vias for electrical connections based on a microchannel plate.

Specifically, the present invention pertains to a semiconductor substrate structure with through vias for electrical connection, comprising: (a) a microchannel plate substrate wherein multiple microchannels arranged parallel and adjacent to each other at a predetermined angle to the surface; (b) vias formed by utilizing one or more of the microchannels in the substrate as via holes; and (c) insulating layers covering the top and bottom of the substrate in regions excluding the vias.

In the semiconductor substrate structure of the present invention, the vias may be formed by utilizing two or more adjacent microchannels as via holes. Furthermore, the vias may be formed by utilizing merged regions as via holes, where the walls between two or more adjacent microchannels have been removed. The vias may be formed either by filling the microchannels with conductive material or by stacking multilayer thin films including a conductive material layer along the microchannel walls. At least some of the microchannels not used as via holes in the semiconductor substrate structure may have internal pressure below atmospheric pressure, or may be filled with polymers.

Another aspect of the present invention pertains to a method for manufacturing the aforementioned semiconductor substrate structure. Specifically, the method for manufacturing the semiconductor substrate structure comprises: (A) preparing a microchannel plate substrate wherein microchannels are arranged parallel and adjacent to each other at a predetermined angle to the surface; and (B) forming vias by either filling conductive material into the microchannels designated as via holes or by forming conductive films on their walls.

Between steps (A) and (B), the method may optionally include step (A′) of removing walls between multiple microchannels designated as via holes.

Yet another aspect of the present invention pertains to a microchannel structure comprising expanded channels formed by removing and merging between walls two or more adjacent microchannels in a microchannel plate substrate, wherein multiple microchannels are arranged parallel and adjacent to each other at a predetermined angle to the surface. This microchannel structure serves as a precursor for the semiconductor substrate structure of the present invention. Furthermore, it can be applied to the fabrication of fluidic devices.

As described above, since the semiconductor substrate structure of the present invention uses pre-formed micro-diameter, high aspect ratio microchannels in the microchannel plate for via formation, it can form high-density, high-quality vias with smaller diameters at lower process costs compared to conventional vias formed by etching processes or laser drilling processes. Additionally, air gaps can be easily formed using microchannels around the vias that are not filled with conductive layers, even without undergoing separate processes. In this case, the air gaps are enclosed by insulating layers at the top and bottom, and the interiors can be filled with polymers or maintained at atmospheric pressure or be in a vacuum state. These air gaps function to lower the fringing capacitance around the vias or reduce the capacitance between the wiring layers above and below the microchannels. Furthermore, using multiple through-holes to form vias enhances the semiconductor substrate structure's electrical and thermal characteristics by increasing the contact area with surrounding insulators and distributing stress.

Moreover, the semiconductor substrate structure of the present invention, which forms vias by utilizing microchannels in the microchannel plate substrate, can be extended for applications in various high-density semiconductor packaging technologies and can be effectively utilized in interposers, copper-clad laminates, and interlayer dielectric films.

The microchannel structure generated during the manufacturing process of the semiconductor substrate structure of the present invention includes microchannels that are expanded through merging, which can be used for the production of fluidic devices by utilizing the expanded microchannels as flow paths.

### BRIEF DESCRIPTION OF THE DRAWINGS

FIG. 1 shows a schematic diagram of a microchannel plate.

FIG. 2A to 2E show cross-sectional views of semiconductor substrate structures in accordance with embodiments of the present invention.

FIG. 3 shows a schematic diagram of an interposer incorporating the semiconductor substrate structure of the present invention.

FIG. 4 shows a schematic diagram of an active interposer incorporating the semiconductor substrate structure of the present invention.

FIG. 5 shows a flowchart of the manufacturing method for the semiconductor substrate structure of the present invention.

FIG. 6 to FIG. 8 show schematic diagrams of the manufacturing process for the semiconductor substrate structure according to embodiments of the present invention.

### DETAILED DESCRIPTION

The present invention will now be described in more detail with reference to the accompanying drawings and embodiments. However, these drawings and embodiments are provided merely to facilitate explanation of the technical content and scope of the present invention and should not be construed as limiting or modifying the technical scope of the present invention. Based on these examples, those skilled in the art will understand that various modifications and variations are possible within the scope of the technical concept of the present invention. Furthermore, when explaining the invention, detailed descriptions of well-known technologies related to the invention may be omitted if they are deemed to unnecessarily obscure the essence of the invention.

In the drawings of this specification, for the convenience of explanation, the sizes, thicknesses, or shapes of some components may be exaggerated or simplified. Accordingly, the sizes or thicknesses of the components shown in the drawings do not reflect actual proportions. Furthermore, throughout this specification, when it is stated that a certain part “includes” a component, unless specifically stated otherwise, it does not exclude the inclusion of other components but means that additional components may also be included. Additionally, when layers, films, regions, or plates are described as being “on” or “above” other parts, this includes cases where they are “directly on” the other parts as well as cases where other parts exist between them. Conversely, when it is stated that something is “directly on” another part, it means there are no other parts in between. Similarly, when layers, films, regions, or plates are described as being “below” or “under” other parts, this includes cases where they are “directly below” as well as cases where other parts exist between them. Conversely, when something is stated to be “directly below” another part, it means there are no other parts in between. Also, when it is stated that something is formed “entirely” on another part or above/below another part, this includes not only cases where it is formed on the entire surface or above/below the entire surface of the other part but also cases where it is not formed on some edges or above/below some portions. In this specification, “/” and “and/or” are considered to describe each specific feature or component as being present or absent independently from another. For example, “A/B” or “A and/or B” should be interpreted as having the same meaning as if (i) A, (ii) B, and (iii) A and B were each independently described.

As described above, the present invention pertains to a semiconductor substrate structure featuring through vias for electrical connections based on a microchannel plate. The semiconductor substrate structure of the present invention comprises a microchannel plate substrate wherein multiple microchannels arranged parallel and adjacent to each other at a predetermined angle to the surface; vias formed by utilizing one or more of the microchannels in the substrate as via holes; and insulating layers covering the top and bottom of the substrate in regions excluding the vias.

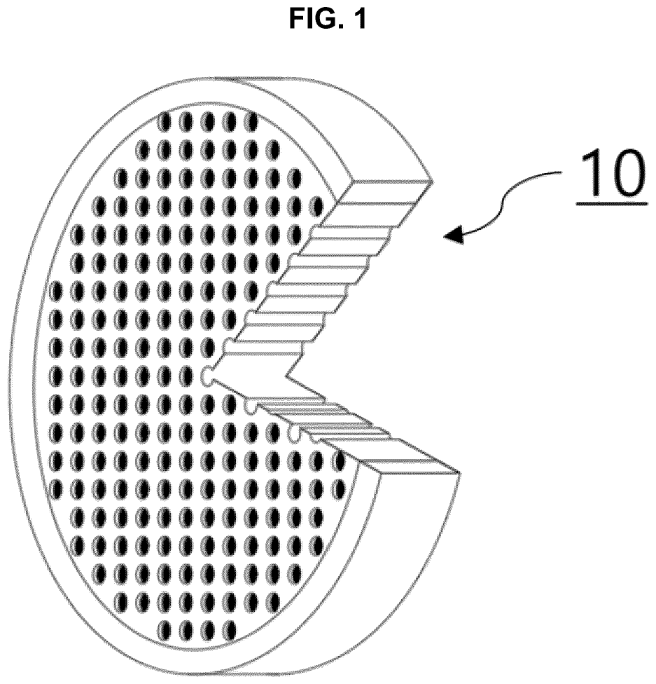

The first characteristic of the semiconductor substrate structure (1) of the present invention is that the substrate (10) is a microchannel plate. A microchannel plate is a substrate containing multiple holes (i.e., microchannels (11)) of uniform micro-diameter penetrating from one surface to another, arranged at a predetermined angle to the surface. Preferably, the microchannels are arranged perpendicular to the surface. While FIG. 1 illustrates a circular microchannel plate, it is obvious that the shape is not limited to being circular. In the microchannel plate, the microchannels may be formed throughout the entire substrate, or as shown in FIG. 1, may partially include regions without microchannels. FIG. 1 illustrates a substrate that includes regions without microchannels along its edges, but this is not limited thereto. The ‘region with microchannels’ includes both the microchannels (11) and the walls (12) between microchannels. The ‘region without microchannels’ is the opposite concept of ‘region with microchannels’ and specifically refers to regions with an aperture ratio of 5% or less. The aperture ratio represents the ratio of the total cross-sectional area of microchannels to the cross-sectional area of the corresponding region. For example, the area with microchannels in the substrate may be 50% or more, and more preferably 70% or more.

The second characteristic of the semiconductor substrate structure of the present invention is that vias (20) are formed by utilizing one or more of the microchannels in the substrate as via holes.

A via can be formed by either filling conductive material into a microchannel or by depositing conductive films on the microchannel walls. The conductive film may be a single layer or multiple layers. In the case of multiple layers, one or more layers are formed of conductive material and exhibit conductivity, and one or more non-conductive layers may also be included. The conductive film is formed parallel to the microchannel walls and can fill the entire internal space of the microchannel, but it is not necessary for the microchannel to be completely filled. A Via provides vertical electrical connection through the substrate and the conductive material may be a precious metal or metal, specifically Ti, Cu, Ag, Pd, W, or there combinations. Preferably, the conductive material is copper.

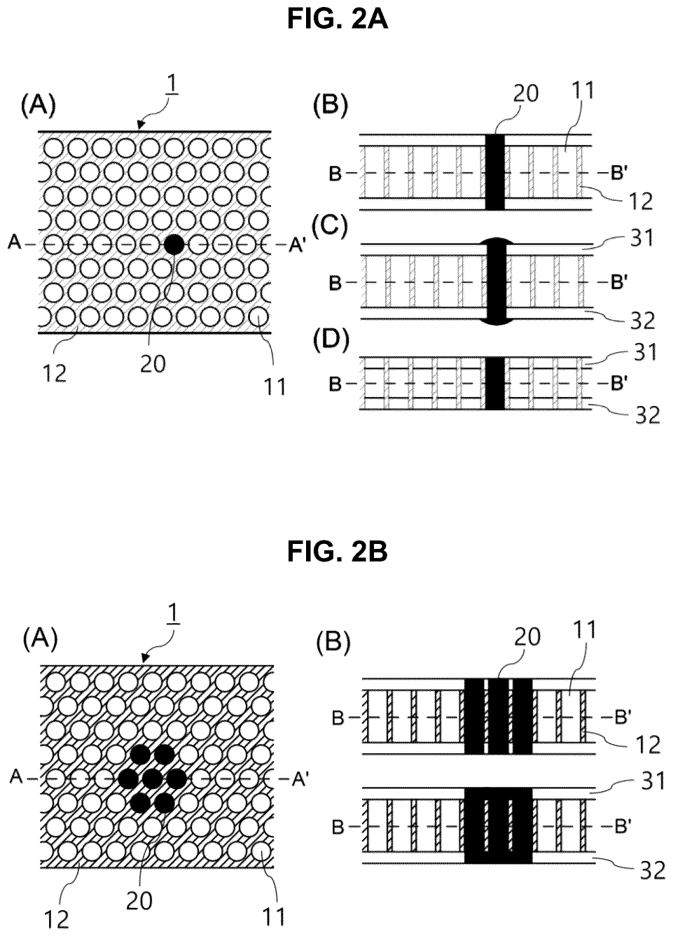

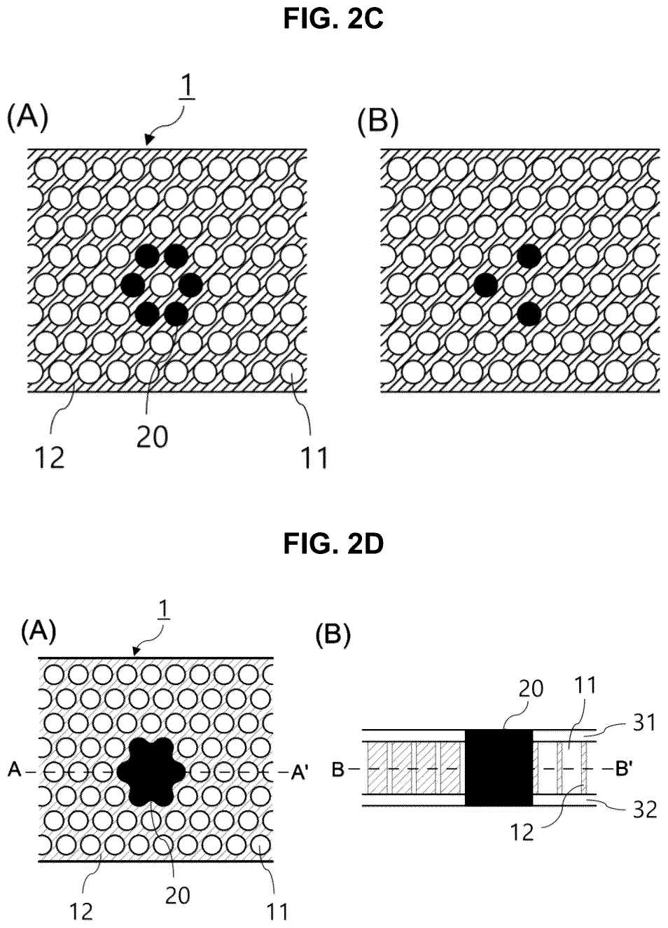

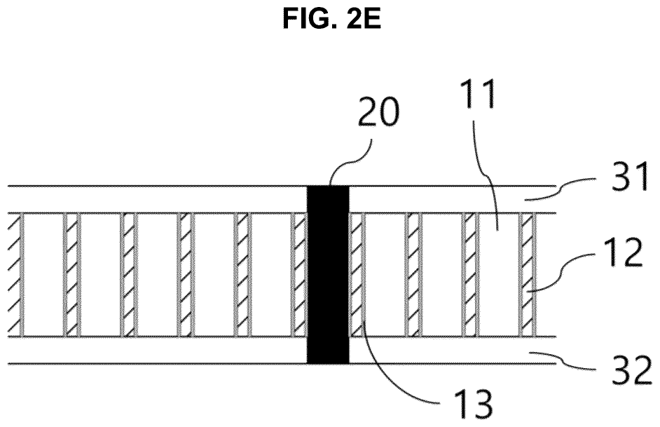

FIG. 2A shows a schematic diagram of an exemplary semiconductor substrate structure with a via formed by filling conductive material into a single microchannel. In FIGS. 2A to 2E, (A) shows a cross-sectional view (B-B′) of the semiconductor substrate structure, while (B) (to (D)) shows longitudinal cross-sectional views (A-A′). In most examples of FIGS. 2A to 2E, the conductive material of the via is shown to be filled up to the same height as the insulating layer. However, it can be formed higher than the insulating layer as shown in (C) of FIG. 2A when necessary. It may also be formed lower than the insulating layer (not shown); for example, in (B) of FIG. 2A, the conductive material may be filled only up to the height of the microchannel. In this case, electrical connection can be achieved by forming conductive pads on the via or making contact with bumps in the semiconductor device or packaging process using the semiconductor substrate structure. As shown in (C) of FIG. 2A, the upper surface of the via may be curved and/or optionally, the edges of the insulating layer at the via interface may be covered with conductive material. It is obvious that the patterns of conductive material may differ between the top and bottom of the substrate. While the drawings show the diameter of the conductive material-filled region in the insulating layer as being equal to the microchannel diameter, it can be larger than the microchannel diameter as long as it does not connect with the immediately adjacent microchannel, and it can also be smaller than the microchannel diameter (not shown). Although the drawings explain based on an example where the via is formed by filling a single conductive material into a microchannel used as a via hole, the via can also be formed by conductive thin films or multilayer thin films parallel to the microchannel walls, optionally with sealed ends. In the case of multilayer thin films, at least one layer must be formed of conductive material to constitute a via. When forming the via with thin films, the via hole may not be completely filled.

The top and bottom of the substrate, excluding the via regions, are each covered by insulating layers (31, 32), so electrical connection is enabled only through the vias. The ‘top’ or ‘bottom’ of the substrate is not an absolute orientation determined by the usage of the semiconductor substrate structure, but rather a relative concept. That is, when one side of the substrate is designated arbitrarily as the ‘top’ for convenience of explanation, the opposite side becomes the ‘bottom’. The insulating layers can be formed as separate continuous layers on the upper and lower surfaces of the microchannel plate, as shown in (B) or (C) of FIG. 2A. Alternatively, as shown in (D) of FIG. 2A, they can be a layers that cap the top and bottom of individual microchannels in regions excluding the vias. Or they can be in a form where separate continuous layers are formed on the upper and lower surfaces of the substrate while also capping the tops and bottoms of the microchannels, and the top and bottom insulating layers may differ in structure. Hereinafter, the semiconductor substrate structure of the present invention will be described using drawings in which the insulating layers are formed as separate continuous layers. However, based on the above description, a person skilled in the art would be able to easily derive a semiconductor substrate structure that includes insulating layers capping the top and/or bottom of individual microchannels. The insulating layers can be formed using silicon oxide, silicon nitride, or silicon oxynitride, but are not limited to these materials. The insulating layers formed on the top and bottom may be composed of the same material or different materials. They may also be the same as or different from the material of the microchannel plate substrate.

When the microchannel diameter is very small, such as 0.1 μm, the via diameter also becomes small, leading to increase resistance and heat generation. Additionally, the via diameter may be too small to ensure proper alignment of the wiring. In such cases, as shown in FIG. 2B, the semiconductor substrate structure can be designed to provide a single electrical connection by forming vias in two or more adjacent microchannels. FIG. 2B illustrates an example wherein seven symmetrically shaped vias are formed using seven microchannels to provide a single electrical connection, but the structure does not necessarily need to be symmetrical. It would be feasible to design the via shape to align efficiently according to the wiring pattern. As shown in (B) of FIG. 2B, insulating layers may be formed between each via (upper diagram), or they may be interconnected with conductive material to enhance the stability of electrical connection (lower diagram). The substrate's upper surface may have insulating layers formed between adjacent vias while the lower surface may have adjacent vias electrically connected by conductive material, or vice versa. It is also possible to have some areas formed with insulating layers and some areas electrically connected to the conductive material constituting the vias.

To form one via, 2˜100 adjacent microchannels can serve as via holes for constituting the via. Here, ‘adjacent’ does not necessarily mean being immediately next to each other but should be understood as being within a range that provides the same electrical connection through the same via. FIG. 2C shows cross-sectional views of exemplary semiconductor substrate structures containing vias where two or more adjacent microchannels are used as via holes, but immediately adjacent microchannels are not used as via holes. As shown in (A) of FIG. 2C, some of the immediately adjacent microchannels may not serve as vias, and furthermore, as shown in (B), even if none of the immediately adjacent microchannels are utilized as vias, vias formed in adjacent microchannels can provide a single electrical connection. Naturally, the via can be constructed in a form that combines two or more of the structures shown in FIGS. 2A˜2C.

As the aperture ratio of the ‘region with microchannels’ in the microchannel plate decreases, it may become more difficult to accurately align vias for precise wiring placement. Or, even when forming vias in two or more microchannels, to further improve electrical and thermal characteristics, it may be desirable to increase the cross-sectional area of conductive material for the same via area. In this case, it is more preferable for the via to be formed by utilizing a merged region as a via hole wherein walls between two or more adjacent microchannels have been removed. When using a merged region as a via hole, the cross-sectional area of the via hole increases, thereby facilitating the filling of conductive material or the formation of conductive thin films. FIG. 2D illustrates an example of a symmetrically shaped via formed using a merged region wherein walls between seven microchannels have been removed. In this case as well, the via hole for forming the via can be a merged region derived from between 1 and 100 adjacent microchannels.

It is obvious that the semiconductor substrate structure of the present invention may include multiple vias providing independent electrical connections.

The microchannel plate substrate may be made of glass, silicon oxide, silicon, or a polymer material. The microchannel plate may have a separate glass layer (13) on the inner walls of the microchannels. FIG. 2E shows an exemplary longitudinal cross-sectional view of a semiconductor substrate structure with vias from the structure of FIG. 2A, wherein a separate glass layer (13) is formed. While FIGS. 2A˜2D illustrate examples where microchannels are arranged orthocyclically, this is not limiting. For example, microchannels can be simply stacked in layers or arranged in an irregular manner. The diameter of each microchannel is preferably 0.1˜500 μm, more preferably 0.1˜100 μm, and even more preferably 0.1˜30 μm. The aspect ratio of the microchannels can be 10˜1,000. In the microchannel plate, smaller microchannel diameters, higher microchannel density, and higher aperture ratios lead to better wiring alignment precision, enabling high-density electrical connections. To achieve excellent wiring alignment and electrical connection, the microchannel plate substrate is preferably composed of 103 or more microchannels/mm². The aperture ratio of the microchannel plate serves as an another indicator of microchannel density, representing the ratio of microchannel (hole) cross-sectional area to the microchannel plate's cross-sectional area. The aperture ratio is naturally calculated only for regions where microchannels are formed, and in these regions, the aperture ratio can be 25-80%. The aperture ratio is preferably 40% or higher, more preferably 50% or higher. It would be feasible for those skilled in the art to select a microchannel plate substrate with appropriate diameter, aperture ratio, and aspect ratio considering the semiconductor substrate structure's application field.

Conventional semiconductor substrate structures with electrical connection vias, particularly in the case of TSV (Through-Silicon Via), required additional processes to reduce the substrate's dielectric constant. For example, air gaps were formed around the vias, or insulating films formed using low-k materials between the through-holes for via formation and conductive materials. The semiconductor substrate structure of the present invention uses a microchannel plate as the substrate, and vias are formed by filling conductive material into some microchannels or by forming conductive thin films in some microchannels. This allows microchannels to remain arranged in the surrounding substrate regions, particularly around the vias. In the semiconductor substrate structure of the present invention, since the microchannels around the vias serve as air gaps, there is no need to form air gaps through additional processes. Additionally, when using a microchannel plate substrate with glass layers acting as a low dielectric material on the microchannel inner walls, there is no need to form separate insulating films. At least some of the microchannels excluding the vias may be filled with air or nitrogen, or may be in a vacuum state.

If necessary, to control the substrate's electrical and/or thermal characteristics, at least some of the microchannels can be filled with polymers, glass, polycrystalline silicon, metal oxides, metal nitrides, polysilazane (PSZ), or the like. It would be feasible for those skilled in the art to select materials for filling the microchannels by considering the characteristics of materials known in conventional technology to achieve appropriate thermal and electrical characteristics according to the semiconductor substrate structure's purpose and application field. The dielectric constant, thermal conductivity, and thermal stability of the semiconductor substrate structure can be controlled based on the materials filled in the microchannels and the location and ratio of filled microchannels. When polymers are filled, their precursors should preferably have sufficient fluidity to fill microchannels with small diameters.

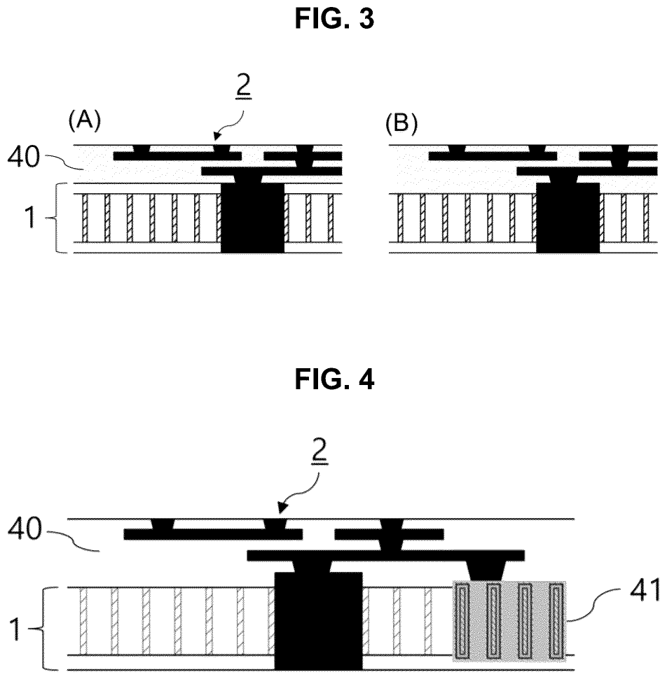

The semiconductor substrate structure of the present invention may include additional components or functional layers. For example, the semiconductor substrate structure of the present invention can be used as an interposer by forming a redistribution layer. An interposer is used to electrically connect semiconductor chips and substrates with large pitch differences. FIG. 3 shows an example of an interposer (2) using the semiconductor substrate structure of the present invention. As shown, the interposer includes a redistribution layer (40) formed on the semiconductor substrate structure of the present invention. The redistribution layer is an electrical circuit formed within the insulating layer through a patterning process, optimizing electrical connection between semiconductor chips and substrates through vias. The redistribution layer can have a single-layer or multilayer structure. As shown in (A) of FIG. 3, the insulating material of the redistribution layer may be different from that of the insulating layer of the semiconductor substrate structure of the present invention. Alternatively, as shown in (B) of FIG. 3, the insulating material of the redistribution layer may be integrated with the insulating layer of the semiconductor substrate structure, being made of the same material.

Additional components or functional layers may include, for example, protective coatings for protecting the semiconductor substrate structure from external moisture, dust, chemicals, and mechanical damage. Alternatively, there may be a heat dissipation layer or active cooling device formed to manage or disperse heat within the semiconductor substrate structure. Naturally, other functional layers or structural elements can also be included.

The semiconductor substrate structure may be a structure primarily focused on wiring functions providing electrical connections, but it may also include additional components. Additional components can include transistors, integrated circuits (ICs) for power management or signal processing, DC/DC converters, etc. These components may be included in the ‘region without microchannels’ of the substrate. Alternatively, they may be multilayer thin film devices formed in one or more microchannels. Specifically, the multilayer thin film device may be the device disclosed in the present inventors' Korean Patent No. 10-2546090. FIG. 4 shows an example of an interposer wherein such multilayer thin film devices (41) are embedded in the semiconductor substrate structure of the present invention. Specific examples of embedded multilayer thin film devices can include one or more of transistors, capacitors, all solid-state batteries, thermocouple devices, and energy harvesting devices, but are not restricted to these examples.

Another aspect of the present invention pertains to a copper-clad laminate including the aforementioned semiconductor substrate structure. The copper-clad laminate of the present invention includes copper cladding both above the insulating layer on the substrate's upper surface and below the insulating layer on the substrate's lower surface. Conventional copper-clad laminates use reinforcing materials such as glass fiber or paper to complement the mechanical strength of the base resin. In the copper-clad laminate according to the present invention, when using a microchannel plate made of glass or silicon oxide, it can resolve the problems of conventional copper-clad laminates without separate reinforcing materials due to its excellent insulation properties, mechanical strength, and dimensional stability against temperature. Additionally, when using a polymer microchannel plate, not only are the insulating properties further enhanced, but the microchannels can also serve as a buffer for dimensional changes in the polymer. Furthermore, it is obvious that mechanical strength or electrical properties can be improved by appropriately selecting materials to be filled in the microchannels.

Another aspect of the present invention pertains to an interlayer dielectric film including the aforementioned semiconductor substrate structure. The interlayer dielectric film can be effectively used in semiconductor devices owing to its superior insulation properties provided by multiple air gaps, combined with excellent mechanical properties.

Semiconductor chips are used in the form of semiconductor packages to supply necessary power to the semiconductor chips, provide electrical signal connections between chips and/or between chips and substrates, and protect them from external moisture and impurities. Another aspect of the present invention pertains to a semiconductor package including the aforementioned semiconductor substrate structure. The semiconductor substrate structure of the present invention can be used as an interposer to electrically connect between semiconductor chips and/or between chips and substrates. The semiconductor substrate structure with through vias according to the present invention can be effectively utilized in 2.5D or 3D packages to enable high-density electrical connections.

According to another aspect, the present invention pertains to a method for manufacturing the aforementioned semiconductor substrate structure. Specifically, the method for manufacturing the semiconductor substrate structure comprises:
(A) preparing a microchannel plate substrate wherein microchannels are arranged parallel and adjacent to each other at a predetermined angle to the surface; and
(B) forming vias by either filling conductive material into the microchannels designated as via holes or by forming conductive films on their walls.

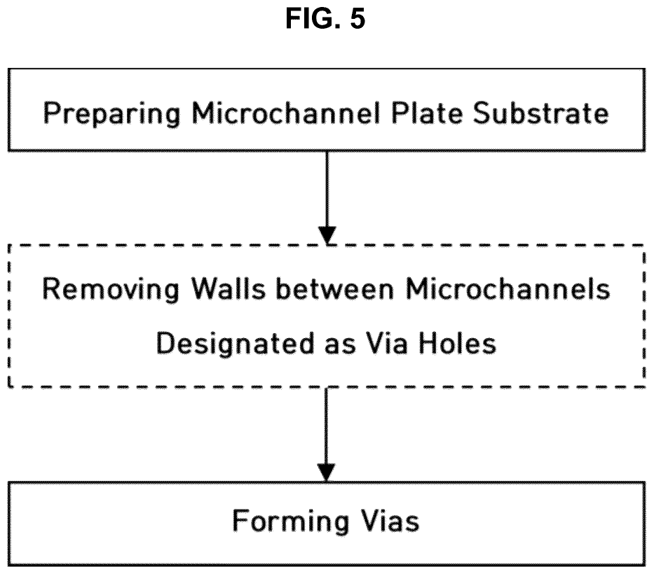

FIG. 5 shows a flowchart of the manufacturing method for the semiconductor substrate structure.

Step (A) is the step of preparing a microchannel plate to serve as the substrate for manufacturing the semiconductor substrate structure of the present invention.

Glass microchannel plates with a thickness of 0.2˜1.5 mm, containing microchannels with diameters ranging from 1 to several hundred μm that are densely and regularly arranged at an aperture ratio of 50% or more, are already commercialized and used in various fields. Currently, semiconductor substrate structures with through vias such as TSV (Through-Silicon Via) or TGV (Through-Glass Via) have via diameters ranging from 10 to several hundred μm and aspect ratios in the range of 1˜10. Since TSV and TGV are manufactured by etching, drilling, or laser ablation, process costs increase rapidly as the via diameter decreases and the aspect ratio increases. Glass microchannel plates are manufactured by slicing bundles produced through repeated drawing and stacking techniques into desired thickness and at a specific angle. Therefore, the diameter becomes smaller as the number of drawing operations increases, and the aspect ratio can be freely adjusted by controlling the slicing thickness. They also have the advantage of very uniform and smooth inner walls in the microchannels. Microchannel plates made of amorphous silicon or aluminum oxide are also known. The present invention may employ such commercial or known microchannel plates.

Specifically, when the microchannel plate is a glass microchannel plate, it may be manufactured by the method comprising:
(a) drawing capillaries;
(b) stacking the drawn capillaries;
(c) fusing the stacked capillaries to produce a capillary bundle; and
(d) slicing the capillary bundle to produce plates.

Optionally, the method may include repeating steps (a)˜(c) one or more times using the capillary bundle from step (c) as capillaries.

Alternatively, the microchannel plate can also be manufactured applying the method from Korean Patent No. 10-2563382 by the present inventors. This patent provides a method for manufacturing a microchannel plate comprising: (A) coating the surface of one or more strands of microfiber with a predetermined diameter with a polysilazane or polysiloxane binder; (B) winding one or more strands of binder-coated microfiber onto a bobbin to form a microfiber bundle; (C) curing the binder while the shape of the microfiber bundle is fixed; and (D) slicing the binder-cured microfiber bundle to manufacture the plate. When the microfiber is a hollow glass structure, step (D) forms a microchannel plate wherein the through-holes of the hollow glass constitute the microchannels. Alternatively, when the microfiber comprises a material selected from polymers, metals, and silicon, the microchannel plate can be formed by removing the polymer, metal, or silicon portions constituting the microfiber after step (D). This method enables the economical production of microchannel plates through a continuous automated process that minimizes repetitive drawing and stacking processes. In particular, this method allows for the production of microchannel plates with diameters ranging from 0.1 to 30 μm, and even for aspect ratios exceeding 1000, high-quality through-holes (microchannels) can be formed.

By applying the method of the above-registered patent and appropriately selecting the materials for the microfibers and binders, microchannel plates made of various materials can be manufactured.

Specifically, the microchannel plate of step (A) can be manufactured by comprising the steps of: (a) producing a microfiber bundle by winding one or more strands of hollow microfibers onto a bobbin; (b) fusing the hollow microfibers while maintaining the microfiber bundle's shape; and (c) slicing the fused microfiber bundle to produce plates. For example, glass or polymer microfibers can be fused through heat treatment. When the material of the microfibers is difficult to self-fuse, microfibers coated with a binder on their surface can be used in step (a). The microfiber wound around the bobbin can be a single microfiber strand, or multiple strands of microfibers, that is, a microfiber cluster. When referring to a binder-coated microfiber cluster, it means that the individual microfibers constituting the cluster are coated. The binder coating of the microfiber cluster can be achieved not only by coating individual microfibers with binder to form bundles but also by applying the binder directly onto an already-formed microfiber cluster. In all the following examples, while the microfiber wound on the bobbin is simply referred to as “microfiber,” it should be interpreted to include both single strands of microfiber and microfiber clusters. The binder can be appropriately selected based on the material of the microchannel plate substrate. For glass or silicon oxide microchannel plates, polysiloxane or polysilazane can be used as the binder, as described in the registered patent. For polymer microchannel plates, polymer precursors can be used as binders. For example, to manufacture a polyimide microchannel plate, polyimide precursors such as polyimide varnish can be utilized. In the case of glass, the separate glass layer may not exist as a separate layer as it may be bonded and integrated by the binder.

In this process, since the microfibers have a hollow structure, the sliced plate itself directly serves as a microchannel plate and can be used without additional processing. For example, if the microfibers are hollow glass and the binder is also a polysiloxane or polysilazane binder, the sliced plate becomes a glass microchannel plate. When manufactured using hollow glass microfibers with a polymer binder, a polymer microchannel plate can be obtained, wherein glass layers are formed inside the microchannels, as shown in FIG. 2E. The microfibers can optionally be removed from the microchannel plate. If the microfibers are removed (for example, by etching) from a microchannel plate manufactured using hollow glass microfibers and polymer binder, a polymer microchannel plate can be obtained.

If the microfiber has a solid structure, a microchannel plate must first be produced by slicing the microfibers into plates and then removing the microfibers. Furthermore, to form high-quality microchannels through the selective removal of microfibers, it is critical to select a binder that facilitates their selective removal. That is, the manufacturing process comprises the steps of: (a) coating the surface of solid structure microfibers with a binder; (b) winding binder-coated microfibers onto a bobbin to form a microfiber bundle; (c) curing the binder while maintaining the microfiber bundle's shape; (d) slicing the cured microfiber bundle to produce plates; and (e) removing the microfibers from the plates. The material of the resulting microchannel plate is determined by the binder material. For example, if polymer microfibers are used with a polysiloxane binder, a glass microchannel plate can be produced. Conversely, if glass microfibers are used with a polymer binder, a polymer microchannel plate can be produced.

Core-shell microfibers can also be used, wherein at least a sacrificial layer is in the core. “At least a sacrificial layer is in the core” means that the entire microfiber can serve as a sacrificial layer, or in a core-shell structure, the shell remains stable while only the core portion serves as a sacrificial layer. In this case, the sacrificial layer is selectively removed after slicing the microfiber bundle to produce plates. The sacrificial layer can be selected based on the material of the microchannel plate. For example, when manufacturing a polyimide microchannel plate, since polyimide is stable in HF etching solution, glass rod-shaped microfibers or polyimide microfibers with glass cores can be used. When manufacturing a glass microchannel plate, since glass is stable in acid, metals that can be easily removed in acid solution can be used as microfibers. The material and removal method of the sacrificial layer are well-established in prior art, so detailed explanation is omitted. Korean Patent No. 10-2563382 discloses in detail the manufacture of microchannel plates using bobbins, and the entire content is incorporated by reference.

When using a microchannel plate with microchannel diameters in the range of 10˜a few hundred μm, since these microchannel diameters correspond to current via diameters, a via can be formed in a single microchannel. During via formation, to prevent conductive material from filling or conductive thin films from forming in microchannels that are not used as via holes, patterns can be formed using lithography. Insulating layers can be formed at appropriate steps in combination with lithography. Insulating layers can be formed either before or after via formation.

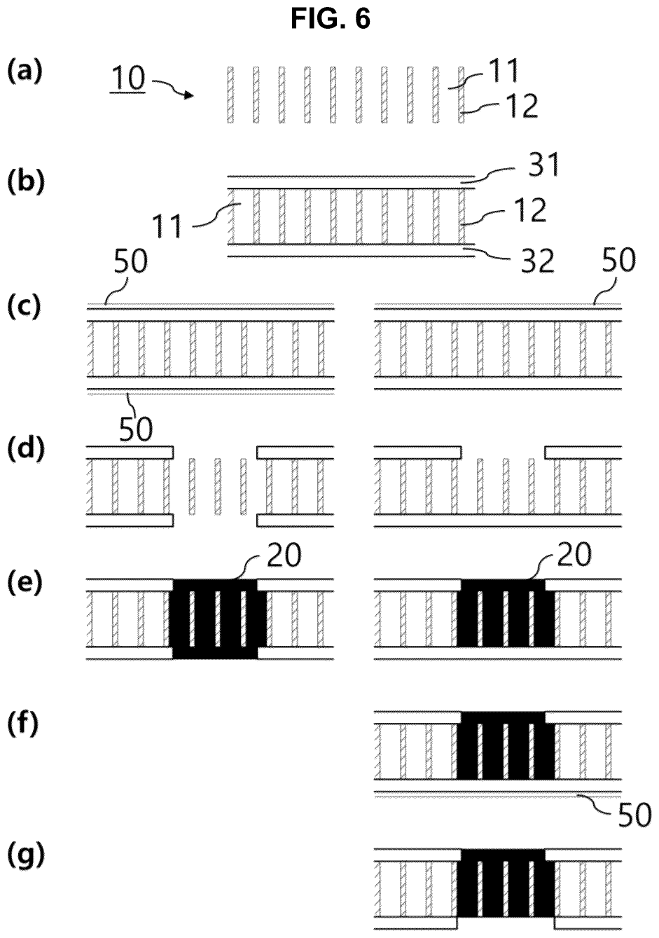

FIG. 6 shows a schematic diagram explaining the manufacturing method of a semiconductor substrate structure according to one embodiment. (a) shows a longitudinal cross-section of the microchannel plate. First, as shown in (b), insulating layers are formed on the top and bottom of the microchannel plate. The insulating layers can be formed of, for example, silicon oxide, silicon nitride, or silicon oxynitride. While FIG. 6 only illustrates examples where the insulating layers are formed as continuous separate films on each upper or lower surface of the microchannel plate, naturally they can also take a form where the tops and bottoms of microcapsules are each capped, as shown in (d) of FIG. 2A. Additionally, while the via is shown as being formed with the insulating layer filled in the microchannel, it can also be deposited on the microchannel walls in the form of single or multilayer thin films. For simplicity of explanation below, the explanation will be based on vias being formed by filling conductive material. The insulating layers can be formed onto the microchannel plate by bonding or deposition. (c) shows resist layers (50) formed on the insulating layers for pattern formation. Depending on whether patterns will be formed on one side or both sides of the substrate, resist layers can be formed on one side (right) or both sides (left) of the substrate. This can be chosen appropriately considering factors including process efficiency. Alternatively, though not separately shown, patterns can be formed only on one side of the substrate to allow both insulating layers to be etched. (d) shows patterns formed after the development process, wherein one or both ends of the microchannels are opened by pattern formation. (e) shows the process of forming vias by filling conductive material into the opened microchannels. While FIG. 6 shows an example where multiple microchannels are opened, only one microchannel may naturally be opened depending on the material of the microchannel plate, the diameter of microchannels, and the purpose of the semiconductor substrate structure. Conductive material may be filled using any conventional methods for through-via formation, such as electroplating or deposition. When patterns are formed only on one side, an additional process is performed: (f) forming resist layers on the opposite side, and (g) etching the insulating layer to expose the vias.

During the above processes, a carrier substrate may be attached as needed to facilitate process execution. For example, when forming patterns on both sides of the substrate, a carrier substrate can be attached below the lower insulating layer between steps (D) and (E). When patterns are formed only on one side of the substrate, a carrier substrate can be attached below the lower insulating layer between steps (B) and (C), and subsequently removed before forming resist layers on the lower insulating layer.

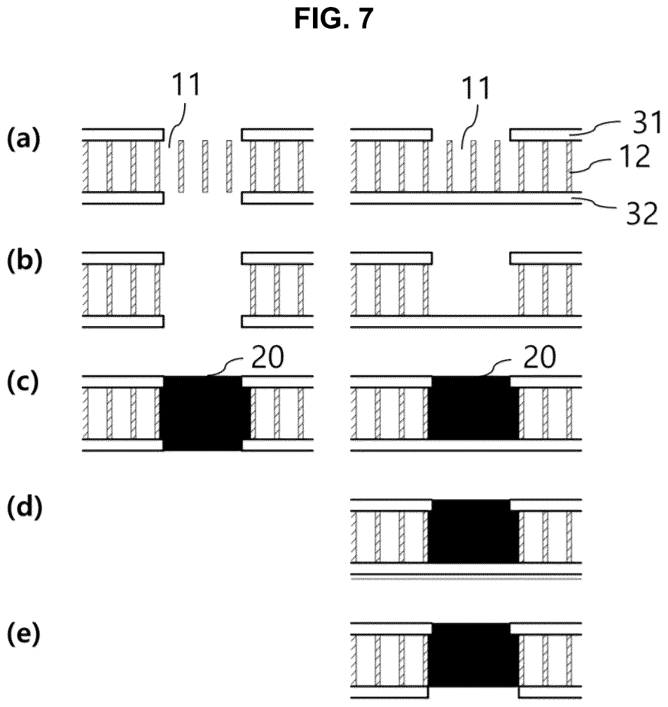

When multiple microchannels are opened, prior to step (B), step (A′) of removing walls between microchannels in the opened region, i.e., walls between multiple microchannels in the region where vias will be formed, may be additionally included. FIG. 7 shows a method for manufacturing a semiconductor substrate structure in which, prior to the conductive material filling step (e) in the process shown in FIG. 6, a wall removal process is added using the structure from (d) in FIG. 6. Wall removal is preferably performed under isotropic etching conditions. Wall removal by etching in the microchannel plate can be performed under mild conditions and can be achieved more easily compared to forming uniform through-holes in conventional substrates. Subsequently, vias are formed by filling conductive material in the opened region. Naturally, as explained in FIG. 6, carrier substrates can be attached at appropriate steps to facilitate the process.

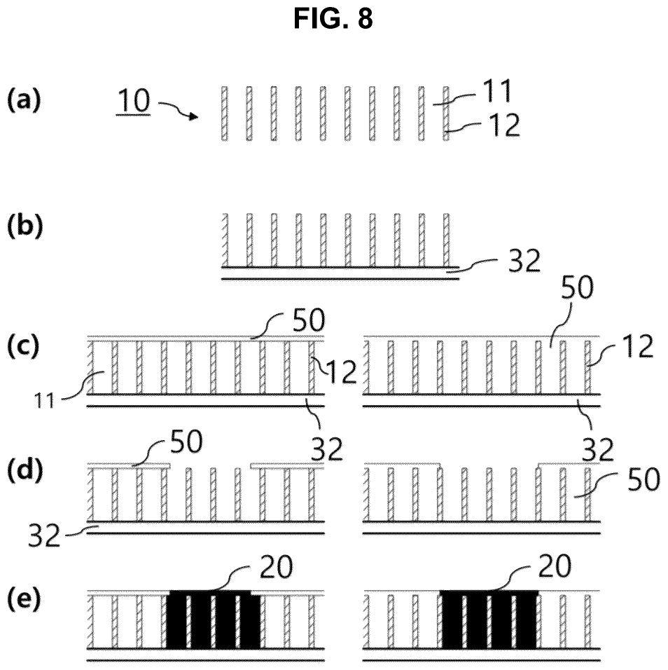

FIG. 8 shows an example of a method for manufacturing a semiconductor substrate structure by first forming an insulating layer on only one side of the microchannel plate. (a) shows a longitudinal cross-section of the microchannel plate substrate, and (b) shows an insulating layer formed only on the bottom of the substrate. (c) shows an example of resist layers formed on the upper surface with the bottom insulating layer formed. The resist layer can be attached as a thin film on the substrate without filling the microchannels using resist film as shown on the left, or formed as a thin film on the substrate with microchannels filled using resist solution as shown on the right. The right diagram shows microchannels completely filled with resist, but naturally they may be only partially filled. When microchannels are filled with resist as shown in the right diagram, during the exposure process, the resist inside the channels is not completely cured, and as etching progresses, the resist in the channels dissolves, forming pattern boundaries at the positions of the microchannel walls. (d) shows the state after forming through vias by filling conductive material after pattern formation. Subsequently, the resist is removed, a top insulating layer is formed with the via portions opened, and the bottom insulating layer is also etched to form through vias (not shown).

When an insulating layer is formed on only one side, patterns can also be formed by forming resist layers on the bottom insulating layer rather than on the top surface where no insulating layer is formed. This can be understood by referring to FIG. 6, even without a separate illustration. In this case, the process can be performed by attaching a carrier substrate to the top surface of the substrate.

Alternatively, vias can be formed by forming patterns after having both the top and bottom of the microchannel plate substrate coated with resist without first forming insulating layers. Then, after removing the patterns, insulating layers are formed to manufacture the semiconductor substrate structure.

A further aspect of this invention relates to a microchannel structure comprising expanded channels formed by removing walls between two or more adjacent microchannels, wherein multiple microchannels are arranged parallel to each other at a predetermined angle to the surface in a microchannel plate substrate. This microchannel structure, which is manufactured by the process shown in FIG. 7, can not only be used as a precursor for the semiconductor substrate structure of this invention but can also be applied to the manufacture of fluidic devices. Examples of fluidic devices include energy exchange devices using refrigerant circulation or bio-fluidic devices. In these devices, the expanded channels serve as fluid pathways.

Although the embodiments of the present invention have been described in detail above, those skilled in the art will understand that various modifications and variations are possible within the spirit and scope of the present invention as defined in the appended claims without departing from them. Additionally, even if certain details explained in a specific embodiment are omitted in other embodiments, unless there are contradicting or conflicting explanations in that embodiment, the content explained in one embodiment can be understood to be equally applicable.

Reference Numerals

| | |
|---|---|
| 1: Semiconductor substrate structure | |
| 10: Microchannel plate substrate | |
| 11: Microchannel | |
| 12: Wall | |
| 13: Glass layer | |
| 20: via | |
| 31: Insulating layer (top) | 32: Insulating layer (bottom) |
| 2: Interposer | |
| 40: Redistribution layer | 41: Multilayer thin film device |
| 50: Resist layer | |

1. A semiconductor substrate structure with through vias for electrical connection, comprising:
a microchannel plate substrate wherein multiple microchannels arranged parallel and adjacent to each other at a predetermined angle to the surface;
vias formed by utilizing one or more of the microchannels in the substrate as via holes; and
insulating layers covering the top and bottom of the substrate in regions excluding the vias.

2. The semiconductor substrate structure according to claim 1, wherein the vias are formed by utilizing two or more adjacent microchannels as via holes.

3. The semiconductor substrate structure according to claim 2, wherein the vias are formed by utilizing merged regions as via holes where walls between two or more adjacent microchannels have been removed.

4. The semiconductor substrate structure according to claim 1, comprising multiple vias providing independent electrical connections.

5. The semiconductor substrate structure according to claim 1, wherein the conductive vias are formed of Ti, Cu, Ag, Pd, W, or combinations thereof.

6. The semiconductor substrate structure according to claim 1, wherein the insulating layers are formed of silicon oxide, silicon nitride, or silicon oxynitride.

7. The semiconductor substrate structure according to claim 1, wherein the microchannel plate substrate is made of glass, silicon oxide, silicon, or polymer.

8. The semiconductor substrate structure according to claim 1, wherein separate glass layers are formed on the inner walls of the microchannels.

9. The semiconductor substrate structure according to claim 1, wherein the aspect ratio of the microchannels is 10˜1,000.

10. The semiconductor substrate structure according to claim 1, wherein the microchannel plate substrate comprises 103 or more microchannels per mm².

11. The semiconductor substrate structure according to claim 1, wherein at least some of the microchannels excluding the vias are filled with air or nitrogen, or are in a vacuum state.

12. The semiconductor substrate structure according to claim 1, wherein at least some of the microchannels excluding the vias are filled with polymer, glass, polycrystalline silicon, metal oxide, metal nitride, or polysilazane.

13. The semiconductor substrate structure according to claim 1, further comprising a heat dissipation layer or active cooling device.

14. The semiconductor substrate structure according to claim 1, further comprising a multilayer thin film device formed in one or more of the microchannels excluding the vias.

15. The semiconductor substrate structure according to claim 14, wherein the multilayer thin film device is one or more selected from transistors, capacitors, all solid-state batteries, thermocouple devices, and energy harvesting devices.

16. A method for manufacturing a semiconductor substrate structure according to claim 1, comprising:
preparing a microchannel plate substrate wherein microchannels are arranged parallel and adjacent to each other at a predetermined angle to the surface; and
forming vias by either filling conductive material into the microchannels designated as via holes or by forming conductive films on their walls.

17. The method according to claim 16, further comprising, Between steps (A) and (B):
(A′) removing walls between multiple microchannels designated as via holes.

18. A microchannel structure comprising expanded channels formed by merging two or more adjacent microchannels through the removal of walls between them in a microchannel plate substrate, wherein multiple microchannels are arranged parallel and adjacent to each other at a predetermined angle to the surface.

19. A fluidic device comprising the microchannel structure of claim 18.

20. The fluidic device according to claim 19, wherein the device is an energy exchange device using refrigerant circulation or a bio-fluidic device.
